(19) United States
(12) Patent Application Publication
(10) Pub. No.: US 2026/0139155 A1
(43) Pub. Date: May 21, 2026

(54) POLISHING AGENT AND METHOD FOR PRODUCING THE SAME, METHOD FOR PRODUCING POLISHING AGENT ADDITIVE LIQUID, POLISHING METHOD, AND METHOD FOR MANUFACTURING SEMICONDUCTOR COMPONENT

(71) Applicant: AGC Inc., Tokyo (JP)

(72) Inventor: Hiroka KOGA, Tokyo (JP)

(73) Assignee: AGC Inc., Tokyo (JP)

(21) Appl. No.: 19/448,285

(22) Filed: Jan. 14, 2026

Related U.S. Application Data
(63) Continuation of application No. PCT/JP2024/025077, filed on Jul. 11, 2024.

(30) Foreign Application Priority Data
Jul. 21, 2023 (JP) 2023-119429

(51) Int. Cl. C09G 1/02; B24B 37/04; H10P 52/40

(52) U.S. Cl. CPC C09G 1/02; B24B 37/044; H10P 52/407

(57) ABSTRACT

A polishing agent contains abrasive grains, an anionic polymer or a salt thereof, and water. The anionic polymer has an acid value of 400 mgKOH/g or less. The polishing agent satisfies at least one of the following conditions: X₁=N₁₁/N₁₂ is 1.5 or less, X₂=N₂₁/N₂₂ is 7.0 or less, and X₃=N₃₁/N₃₂ is 10 or less, where N₁₁, N₂₁, and N₃₁ represent the number of particles contained per unit mass of the abrasive grains in the polishing agent that have a particle size of 0.56 μm or more, 0.79 μm or more, and 0.98 μm or more, respectively; and N₁₂, N₂₂, and N₃₂ represent the number of particles contained per unit mass of abrasive grains in an abrasive grain dispersion containing the abrasive grains, a dispersant, and water that have a particle size of 0.56 μm or more, 0.79 μm or more, and 0.98 μm or more, respectively.

### INCORPORATION BY REFERENCE

This application is based upon and claims the benefit of priority from Japanese patent application No. 2023-119429 filed on Jul. 21, 2023, and PCT application No. PCT/JP2024/025077 filed on Jul. 11, 2024, the disclosure of which is incorporated herein in its entirety by reference.

### BACKGROUND

The present invention relates to a polishing agent and a method for producing the same, a method for producing a polishing agent additive liquid, a polishing method, and a method for manufacturing a semiconductor component.

With an increase in integration and functionality of a semiconductor integrated circuit, development of a micromachining technique for miniaturization and densification of a semiconductor element has been advanced. Conventionally, in manufacture of a semiconductor integrated circuit device (hereinafter, also referred to as a semiconductor device), in order to prevent a problem that unevenness (step) on a layer surface exceeds a focal depth of lithography and sufficient resolution cannot be obtained, an interlayer insulating film, embedded wiring, and the like are planarized using a chemical mechanical planarization method (chemical mechanical polishing: hereinafter referred to as CMP). As a demand for high definition and miniaturization of an element is stricter, an importance of high planarization by CMP is increasing more and more.

Also, in manufacture of a semiconductor device, in order to further miniaturize a semiconductor element, a separation method using a shallow trench having a small element separation width (shallow trench isolation: hereinafter referred to as STI) has been introduced.

STI is a method for forming an electrically insulated element region by forming a trench (groove) in a silicon substrate and embedding an insulating film in the trench. An example of STI will be described with reference to FIGS. 1A and 1B. In this example, first, as illustrated in FIG. 1A, an element region of a silicon substrate 1 is masked with a stopper film 2 or the like, then a trench 3 is formed in the silicon substrate 1, and an insulating film such as a silicon oxide film 4 is deposited so as to fill the trench 3. Subsequently, by polishing and removing the silicon oxide film 4 on the stopper film 2 as a protrusion by CMP while leaving the silicon oxide film 4 in the trench 3 as a recess, an element isolation structure in which the silicon oxide film 4 is embedded in the trench 3 is obtained as illustrated in FIG. 1B.

In CMP in STI, by increasing a selection ratio (polishing speed ratio) between a silicon oxide film and a stopper film, a progress of polishing can be stopped when the stopper film is exposed. Examples of such a stopper film include a nitride film and polysilicon. In the polishing method using the stopper film, a smoother surface can be obtained as compared with a surface obtained by a normal polishing method. A recent CMP technique requires that the selection ratio is high.

For example, Patent Literature 1 discloses a polishing agent containing a specific anionic polymer, cerium oxide particles, and water and having a pH of 4 to 9 as a method for increasing a selection ratio between a silicon dioxide film and a silicon nitride film.

### PATENT LITERATURE 1

Japanese Unexamined Patent Application Publication No. 2019-87660

### SUMMARY

When an anionic polymer having a low acid value was used in the polishing agent containing the anionic polymer, the selection ratio tended to be improved, but polishing scratches sometimes increased.

In view of the above problems, an object of the present disclosure is to provide a polishing agent capable of suppressing the occurrence of polishing scratches while improving the selection ratio by using an anionic polymer having a low acid value. In addition, it is an object of the present disclosure to provide a method for producing a polishing agent additive liquid capable of suitably adjusting the polishing agent, a polishing method using the polishing agent, and a method for manufacturing a semiconductor component using the polishing method.

The present disclosure provides a polishing agent having the following configuration and a method for producing the same, a method for producing a polishing agent additive liquid, a polishing method, and a method for manufacturing a semiconductor component.
[1] A polishing agent containing abrasive grains, an anionic polymer, and water, in which
an acid value of the anionic polymer is 400 mgKOH/g or less, and
X₁ determined from the following formula (1) is 1.5 or less,

$${X}_{1} = {N}_{11} / {N}_{12} \qquad ( 1 )$$

provided that
N₁₁ is the number of particles having a particle size of 0.56 μm or more contained per unit mass of abrasive grains in the polishing agent, and
N₁₂ is the number of particles having a particle size of 0.56 μm or more contained per unit mass of the abrasive grains in an abrasive grain dispersion containing the abrasive grains, a dispersant, and water.
[2] A polishing agent containing abrasive grains, an anionic polymer, and water, in which
an acid value of the anionic polymer is 400 mgKOH/g or less, and
X₂ determined from the following formula (2) is 7.0 or less,

$${X}_{2} = {N}_{21} / {N}_{22} \qquad ( 2 )$$

provided that
N₂₁ is the number of particles having a particle size of 0.79 μm or more contained per unit mass of abrasive grains in the polishing agent, and
N₂₂ is the number of particles having a particle size of 0.79 μm or more contained per unit mass of the abrasive grains in an abrasive grain dispersion containing the abrasive grains, a dispersant, and water.
[3] A polishing agent containing abrasive grains, an anionic polymer, and water, in which
an acid value of the anionic polymer is 400 mgKOH/g or less, and
X₃ determined from the following formula (3) is 10 or less,

$${X}_{3} = {N}_{31} / {N}_{32} \qquad ( 3 )$$

provided that
N₃₁ is the number of particles having a particle size of 0.98 μm or more contained per unit mass of abrasive grains in the polishing agent, and
N₃₂ is the number of particles having a particle size of 0.98 μm or more contained per unit mass of the abrasive grains in an abrasive grain dispersion containing the abrasive grains, a dispersant, and water.
[4] The polishing agent according to any one of [1] to [3], in which the abrasive grains contain at least one selected from the group consisting of silica particles, alumina particles, zirconia particles, cerium compound particles, titania particles, germania particles, composite particles thereof, and core-shell type particles.
[5] The polishing agent according to any one of [1] to [4], in which the abrasive grains contain cerium compound particles.
[6] The polishing agent according to any one of [1] to [5], in which the abrasive grains contain ceria particles.
[7] The polishing agent according to any one of [1] to [6], in which a content of the abrasive grains is 0.01 mass % to 10.0 mass % with respect to a total mass of the polishing agent.
[8] The polishing agent according to any one of [1] to [7], in which the anionic polymer is a copolymer containing a hydrophobic monomer and an anionic monomer.
[9] The polishing agent according to any one of [1] to [8], in which the anionic polymer has a weight average molecular weight of 2,000 to 50,000.
[10] The polishing agent according to any one of [1] to [9], in which a content of the anionic polymer is 0.02 mass % to 5 mass % with respect to a total mass of the polishing agent.
[11] The polishing agent according to any one of [1] to [10], further containing a pH adjuster.
[12] The polishing agent according to any one of [1] to [11], having a pH of 4 to 8.
[13] A polishing method for bringing a polishing surface of a semiconductor substrate and a polishing pad into contact with each other while supplying a polishing agent, and performing polishing by relative movement between the polishing surface and the polishing pad,
in which the polishing agent is the polishing agent according to any one of [1] to [12].
[14] A method for manufacturing a semiconductor component, the method including segmenting a semiconductor substrate having a polishing surface polished by the polishing method according to [13] to obtain a semiconductor component.
[15] A method for producing a polishing agent additive liquid containing a salt of an anionic polymer having an acid value of 400 mgKOH/g or less, the method including the following step (1) or (2):
(1) dissolving an alkali metal salt of the anionic polymer in water; and
(2) dissolving the anionic polymer in an aqueous alkali metal hydroxide solution containing an alkali metal of 1.0 times or more the number of moles of anionic groups calculated from the acid value of the anionic polymer.
[16] The method for producing a polishing agent additive liquid according to [15], in which the alkali metal is at least one selected from lithium, sodium, potassium, rubidium, and cesium.
[17] The method for producing the polishing agent according to any one of [1] to [12], in which the abrasive grains are mixed with the polishing agent additive liquid obtained by the production method according to [15].

According to the present disclosure, it is possible to provide a polishing agent capable of suppressing the occurrence of polishing scratches while improving the selection ratio by using an anionic polymer having a low acid value. In addition, the present disclosure provides a method for producing a polishing agent additive liquid capable of suitably adjusting the polishing agent, a polishing method using the polishing agent, and a method for manufacturing a semiconductor component using the polishing method.

The above and other objects, features and advantages of the present disclosure will become more fully understood from the detailed description given hereinbelow and the accompanying drawings.

### BRIEF DESCRIPTION OF DRAWINGS

FIG. 1A is a view illustrating an example of a polishing method, and is a cross-sectional view illustrating a state of a polishing target before polishing;

FIG. 1B is a view illustrating an example of a polishing method, and is a cross-sectional view illustrating a state of a polishing target after polishing; and

FIG. 2 is a schematic view illustrating an example of a polishing device.

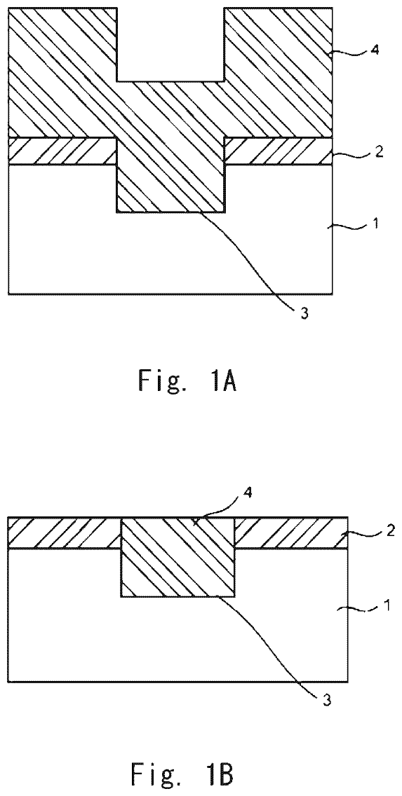

### DESCRIPTION OF EMBODIMENTS

Hereinafter, an embodiment of the present invention will be described. The present invention is not limited to the following embodiment, and other embodiments may also fall within the scope of the present invention as long as they are consistent with the gist of the present invention. For clarity of description, the following description and drawings are simplified as appropriate. In addition, for description, each member in the drawings may be largely different in scale.

Note that, in the present invention, “polishing surface” is a polishing target surface to be polished, and means, for example, a surface. In the present specification, a surface in an intermediate stage appearing in a semiconductor substrate in a process of manufacturing a semiconductor device is also included in the “polishing surface”.

“Silicon oxide” is mainly silicon dioxide, but is not limited thereto, and may contain a silicon oxide other than silicon dioxide.

“Selection ratio” means a ratio (R_{A}/R_{B}) of a polishing speed (R_{A}) of a polishing target A (for example, a silicon oxide film) to a polishing speed (R_{B}) of a stopper film B (for example, a silicon nitride film).

“(Meth)acryl” is a generic term for “methacryl” and “acryl”, and (meth)acryloyl, (meth)acrylate, and the like follow this.

In addition, “to” indicating a numerical range includes numerical values described before and after “to” as a lower limit value and an upper limit value unless otherwise specified.

### [Polishing Agent]

A polishing agent of the present disclosure (hereinafter, also referred to as the present polishing agent) includes abrasive grains, an anionic polymer having an acid value of 400 mgKOH/g or less (hereinafter, also referred to as a “specific anionic polymer”), and water, and satisfies at least one of the following (I), (II), and (III):
(I) X₁ determined from the following formula (1) is 1.5 or less,

$${X}_{1} = {N}_{11} / {N}_{12} \qquad ( 1 )$$

provided that
N₁₁ is the number of particles having a particle size of 0.56 μm or more contained per unit mass of abrasive grains in the polishing agent, and
N₁₂ is the number of particles having a particle size of 0.56 μm or more contained per unit mass of the abrasive grains in an abrasive grain dispersion containing the abrasive grains, a dispersant, and water;
(II) X₂ determined from the following formula (2) is 7.0 or less,

$${X}_{2} = {N}_{21} / {N}_{22} \qquad ( 2 )$$

provided that
N₂₁ is the number of particles having a particle size of 0.79 μm or more contained per unit mass of abrasive grains in the polishing agent, and
N₂₂ is the number of particles having a particle size of 0.79 μm or more contained per unit mass of the abrasive grains in an abrasive grain dispersion containing the abrasive grains, a dispersant, and water; and
(III) X₃ determined from the following formula (3) is 10 or less,

$${X}_{3} = {N}_{31} / {N}_{32} \qquad ( 3 )$$

provided that
N₃₁ is the number of particles having a particle size of 0.98 μm or more contained per unit mass of abrasive grains in the polishing agent, and
N₃₂ is the number of particles having a particle size of 0.98 μm or more contained per unit mass of the abrasive grains in an abrasive grain dispersion containing the abrasive grains, a dispersant, and water.

In the polishing agent satisfying at least one of the (I) to (III), coarse particles are suppressed, and polishing scratches occurred on a polishing surface are suppressed. In addition, the present polishing agent can select an anionic polymer having a relatively low acid value, and the selection ratio can be improved.

The present polishing agent only needs to satisfy at least one of the (I) to (III), and among them, the present polishing agent satisfies preferably the (I), more preferably the (I) and (II), and more preferably all of the (I) to (III).

### <Method for Determining X₁>

First, N₁₁ and N₁₂ are measured by the following methods.

### (Method for Measuring N₁₁)

A polishing agent to be measured is prepared as a test liquid. The polishing agent may be appropriately diluted to be used as the test liquid in consideration of a measurable range of a measuring device. Examples of the diluent for dilution include water or a buffer solution, and water is preferable.

The measurement is performed by an in-liquid particle counter, in a state where the abrasive grains in the test liquid are sufficiently dispersed. Examples of the method for confirming that the abrasive grains are sufficiently dispersed include a method in which the test liquid is stirred at high speed for 24 hours or more using a mixing tumbler, and then it is confirmed that there is no precipitation at the bottom of the container. As the in-liquid particle counter, AccuSizer SIS series manufactured by Entegris or the like can be used. Also, the measurement is performed at a measurement temperature in a range of 28±1° C.

The abrasive grain concentration C₁₁ in the test liquid is adjusted so as to be in the range of 1/100 times to 1 time the recommended concentration of the in-liquid particle counter. Specifically, the lower limit value of the abrasive grain concentration C₁₁ is 1/100000 mass %, preferably 1/50000 mass %, more preferably 1/20000 mass %, and still more preferably 1/15000 mass %. The upper limit value of the abrasive grain concentration C₁₁ is 1/10 mass %, preferably 1/100 mass %, more preferably 1/500 mass %, still more preferably 1/1000 mass %, even still more preferably 1/2500 mass %, and particularly preferably 1/5000 mass %. When the abrasive grains are ceria particles, the abrasive grain concentration C₁₁ is preferably adjusted to about 1/12000 mass %.

By performing the measurement as described above, the number A₁₁ of particles having a particle size of 0.56 μm or more is obtained.

N₁₁, which is the number of coarse particles per unit mass of the abrasive grains, is obtained from the A₁₁ and mass W₁₁ of the abrasive grains in the test liquid (=mass of test liquid×C₁₁) as N₁₁=A₁₁/W₁₁.

### (Method for Measuring N₁₂)

N₁₂ is the number of particles having a particle size of 0.56 μm or more contained per unit mass of abrasive grains in the abrasive grain dispersion as a reference.

First, an abrasive grain dispersion is prepared. As the abrasive grains, the same polishing agent as the polishing agent to be measured is used. For the dispersion of the abrasive grains, a method known that the abrasive grains are hardly aggregated is selected. Examples of the method for dispersing the abrasive grains include (I) a method of coating the surface of the abrasive grains with a polymer and dispersing the abrasive grains by steric repulsion; and (II) a method of dispersing the abrasive grains by electrostatic repulsion between the abrasive grains by setting the zeta potential of the abrasive grains to about ±40 mV by adjusting the pH of the abrasive grain dispersion and/or surface treatment of the abrasive grains.

In the method (I), a polymer and an anionic polymer having an acid value of more than 400 mgKOH/g are preferable, and polyacrylic acid which is a homopolymer of acrylic acid is more preferable.

In the method (II), the zeta potential of the abrasive grains can be adjusted by adding an anionic polymer, an acidic compound, an additive, or the like, and nitric acid or phosphoric acid is preferably used. The zeta potential of the abrasive grains can be measured using, for example, a dynamic light scattering zeta potential measurement device (for example, manufactured by Beckman Coulter, Inc., trade name: DelsaNano C).

The measurement is performed by the in-liquid particle counter, in a state where the abrasive grains in the test liquid are sufficiently dispersed, similarly to the method for measuring N₁₁. The method for confirming that the abrasive grains are sufficiently dispersed is the same as in N₁₁ described above. Also, the measurement is performed at a measurement temperature in a range of 28±1° C. The abrasive grain concentration C₁₂ in the test liquid may be adjusted within the range described in the C₁₁, and when the abrasive grains are ceria particles, it is more preferable to adjust the abrasive grain concentration in the abrasive grain dispersion to about 1/12000 mass %. The measurement is performed in the same manner as in the test liquid by the in-liquid particle counter, and the number A₁₂ of particles having a particle size of 0.56 μm or more is obtained. N₁₂ is obtained from the A₁₂ and mass W₁₂ of the abrasive grains in the abrasive grain dispersion (=mass of abrasive grain dispersion×C₁₂) as N₁₂=A₁₂/W₁₂.

X₁ is calculated by the formula (1) from N₁₁ and N₁₂ measured by the above method. When the abrasive grain concentration C₁₁ in the test liquid and the abrasive grain concentration C₁₂ in the abrasive grain dispersion are the same, X₁ may be obtained as X₁=A₁₁/A₁₂.

When X₁ is 1.5 or less, it is determined that the number of coarse particles in the present polishing agent is small, and the polishing agent can suppress polishing scratches. Among them, X₁ is preferably 1.2 or less, more preferably 1.0 or less, and still more preferably 0.8 or less.

<Method for Determining X₂ and X₃>

X₂ is obtained from the measured values of N₂₁ and N₂₂, and X₃ is obtained from the measured values of N₃₁ and N₃₂ by the formulas (2) and (3), respectively.

For N₂₁ and N₃₁, the number A₂₁ of particles having a particle size of 0.79 μm or more and the number A₃₁ of particles having a particle size of 0.98 μm or more may be counted, respectively, by the same method as the method for measuring N₁₁. A₁₁, A₂₁, and A₃₁ may be obtained simultaneously by one measurement.

For N₂₂ and N₃₂, the number A₂₂ of particles having a particle size of 0.79 μm or more and the number A₃₂ of particles having a particle size of 0.98 μm or more may be counted, respectively, by the same method as the method for measuring N₁₂. A₁₂, A₂₂, and A₃₂ may be obtained simultaneously by one measurement.

When X₂ is 7.0 or less, it is determined that the number of coarse particles in the present polishing agent is small, and the polishing agent can suppress polishing scratches. Among them, X₂ is preferably 5.0 or less, more preferably 2.0 or less, still more preferably 1.8 or less, and particularly preferably 1.5 or less.

Also, when X₃ is 10 or less, it is determined that the number of coarse particles in the present polishing agent is small, and the polishing agent can suppress polishing scratches. Among them, X₃ is preferably 8.0 or less, more preferably 5.0 or less, still more preferably 4.5 or less, and particularly preferably 4.0 or less.

Next, each component that can be contained in the present polishing agent will be described.

### <Abrasive Grains>

In the present polishing agent, the abrasive grains can be appropriately selected and used from those used as abrasive grains for CMP. Examples of the abrasive grains include at least one selected from the group consisting of silica particles, alumina particles, zirconia particles, cerium compound particles (for example, ceria particles and cerium hydroxide particles), titania particles, germania particles, and core-shell type particles having these particles as core particles. Examples of the silica particles include colloidal silica and fumed silica. As the alumina particles, colloidal alumina can also be used.

The core-shell type particle includes a core particle (for example, a silica particle, an alumina particle, a zirconia particle, a cerium compound particle, a titania particle, or a germania particle) and a thin film covering a surface of the core particle.

Examples of a material of the thin film include at least one selected from oxides such as silica, alumina, zirconia, ceria, titania, germania, iron oxide, manganese oxide, zinc oxide, yttrium oxide, calcium oxide, magnesium oxide, lanthanum oxide, and strontium oxide. In addition, the thin film may be formed of a plurality of nanoparticles formed of these oxides.

A particle size of the core particle is preferably 0.01 μm to 0.5 μm, and more preferably 0.03 μm to 0.3 μm.

A particle size of the nanoparticle only needs to be smaller than the particle size of the core particle, and is preferably 1 nm to 100 nm, and more preferably 5 nm to 80 nm.

As the abrasive grains, among the particles described above, silica particles, alumina particles, or cerium compound particles are preferable, and cerium compound particles are more preferable from a viewpoint of an excellent polishing speed of an insulating film, and ceria particles are still more preferable from a viewpoint of obtaining a high polishing speed when the polishing surface includes an insulating film (particularly, a silicon oxide film). In the case of the core-shell type particles, the thin film preferably contains silica, alumina, or a cerium compound, and more preferably contains ceria. The abrasive grains can be used singly or in combination of two or more types thereof.

The content of ceria with respect to the total mass of the abrasive grains is preferably 70 mass % or more, more preferably 80 mass % or more, still more preferably 90 mass % or more, particularly preferably 95 mass % or more, and most preferably 100 mass %. When the content of ceria with respect to the total mass of the abrasive grains is 70 mass % or more, the polishing speed of the insulating film is particularly easily improved.

The ceria particles can be appropriately selected and used from known ceria particles, and examples thereof include ceria particles manufactured by methods described in Japanese Unexamined Patent Application Publication No. H11-12561, Japanese Unexamined Patent Application Publication No. 2001-35818, and Published Japanese Translation of PCT International Publication for Patent Application, No. 2010-505735. Specifically, examples thereof include: ceria particles obtained by adding an alkali to an aqueous solution of cerium(IV) nitrate ammonium to prepare a cerium hydroxide gel, filtering, washing, and firing the cerium hydroxide gel; ceria particles obtained by pulverizing high-purity cerium carbonate, then firing the pulverized cerium carbonate, and further pulverizing and classifying the fired cerium carbonate; and ceria particles obtained by chemically oxidizing a cerium(III) salt in a liquid.

The ceria particles may contain impurities other than ceria, but the content of ceria in one ceria particle is preferably 80 mass % or more, more preferably 90 mass % or more, still more preferably 95 mass % or more, and most preferably 100 mass % (not containing impurities). When the content of ceria in the ceria particle is 80 mass % or more, the polishing speed of the insulating film is easily improved.

An average particle size of the abrasive grains is preferably 0.01 μm to 0.5 μm, and more preferably 0.03 μm to 0.3 μm. When the average particle size is 0.5 μm or less, mechanical action applied to the polishing surface is small, and therefore occurrence of polishing scratches such as scratches on the polishing surface is suppressed. In addition, when the average particle size is 0.01 μm or more, aggregation of the abrasive grains is suppressed, storage stability of the polishing agent is excellent, and the polishing speed is also excellent.

The particle size is the particle size of primary particles when the abrasive grains are not aggregated and dispersed in the liquid. Also, when the abrasive grains are aggregated in the liquid, the particle size is the particle size of the aggregated particles (secondary particles). In either case, the average particle size is measured using a particle size distribution meter such as a laser diffraction/scattering type using a dispersion in which abrasive grains are dispersed in a dispersion medium such as pure water.

The lower limit value of the content of the abrasive grains is preferably 0.01 mass %, more preferably 0.05 mass %, still more preferably 0.1 mass %, even still more preferably 0.2 mass %, and particularly preferably 0.3 mass % with respect to the total mass of the polishing agent. When the content of the abrasive grains is the above lower limit value or more, an excellent polishing speed with respect to the polishing surface can be obtained. On the other hand, the upper limit value of the content of the abrasive grains is preferably 10.0 mass %, more preferably 8.0 mass %, still more preferably 5.0 mass %, particularly preferably 2.0 mass %, particularly more preferably 1.0 mass %, extremely preferably 0.8 mass %, and most preferably 0.5 mass % with respect to the total mass of the polishing agent. When the content ratio of the abrasive grains is the above upper limit value or less, aggregation of the abrasive grains can be suppressed, an increase in viscosity of the present polishing agent is suppressed, and handleability is excellent.

### <Anionic Polymer>

In the present polishing agent, the anionic polymer can be appropriately selected and used from those having an acid value of 400 mgKOH/g or less. By using the specific anionic polymer, polishing of the stopper film is suppressed while maintaining a high polishing speed with respect to the silicon oxide film, a high selection ratio between the silicon oxide film and the stopper film can be obtained, and polishing with high flatness can be implemented.

Examples of the stopper film include a compound containing one or more selected from silicon, carbon, hafnium, zirconium, cobalt, ruthenium, molybdenum, titanium, tantalum, and copper, or a nitride or oxide containing one or more of these, and more specifically, a metal simple substance such as copper, cobalt, ruthenium, molybdenum, titanium, or tantalum; a nitride such as titanium nitride, tantalum nitride, or silicon nitride; an oxide such as zirconia or hafnium oxide; polysilicon, amorphous silicon, hafnium silicate, zirconium silicate, and silicon carbide. Among them, silicon nitride or polysilicon is preferable from a viewpoint of obtaining a higher selection ratio.

From a viewpoint of obtaining a higher selection ratio, the specific anionic polymer is preferably a copolymer containing a hydrophobic monomer and an anionic monomer. Hereinafter, the configuration of the anionic polymer which is the copolymer will be described.

### (Hydrophobic Monomer)

In the present disclosure, the hydrophobic monomer refers to a monomer having a dissolution amount in 100 g of water at 20° C. (hereinafter, also referred to as “solubility”) of 10 g or less. The anionic polymer has a hydrophobic block derived from the hydrophobic monomer, whereby polishing of the stopper film is further suppressed. The solubility is preferably 7 g or less, more preferably 5 g or less, still more preferably 3 g or less, and particularly preferably 2 g or less from a viewpoint of hydrophobic interaction between the anionic polymers.

As the hydrophobic monomer, a monomer having no ionic group or hydrophilic group is preferable, and a compound represented by the following formula (4) is more preferable.

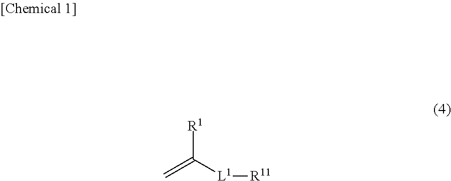

in which
R¹ is a hydrogen atom or a methyl group,
R¹¹ is a hydrocarbon group which may have O or Si between carbon-carbon atoms and in which a hydrogen atom may be replaced with a halogen atom, and
L¹ is a single bond or a divalent linking group.

In the formula (4), R¹¹ is a substituent exhibiting hydrophobicity, and is a hydrocarbon group which may have O or Si between carbon-carbon atoms and in which a hydrogen atom may be replaced with a halogen atom. Examples of the hydrocarbon group in R¹¹ include an alkyl group, an aryl group, and an aralkyl group.

The alkyl group may be linear, branched, or cyclic. The number of carbon atoms in the alkyl group is preferably 1 to 18, and more preferably 1 to 12. Specific examples of the alkyl group include a methyl group, an ethyl group, a n-propyl group, an isopropyl group, a n-butyl group, an isobutyl group, a sec-butyl group, a tert-butyl group, various pentyl groups, various hexyl groups, various octyl groups, various decyl groups, a cyclopentyl group, a cyclohexyl group, a cyclooctyl group, a cyclododecyl group, a bornyl group, and an adamantyl group.

Examples of the aryl group include a phenyl group, a biphenyl group, a naphthyl group, a tolyl group, and a xylyl group. The number of carbon atoms in the aryl group is preferably 6 to 24, and more preferably 6 to 12.

Examples of the aralkyl group include a benzyl group, a phenethyl group, a naphthylmethyl group, and a biphenylmethyl group. The number of carbon atoms in the aralkyl group is preferably 7 to 20, and more preferably 7 to 14.

When R¹¹ has an aromatic ring, a hydrogen atom of the aromatic ring may have a substituent such as a linear or branched alkyl group having 1 to 4 carbon atoms.

The hydrocarbon group in R¹¹ may further have O or Si between carbon-carbon atoms, and in the hydrocarbon group, a hydrogen atom may be replaced with a halogen atom.

Examples of the hydrocarbon group having O or Si between carbon-carbon atoms include an alkylene oxide such as —(CH₂CH₂O)ₓ— or —(CH₂O)ₓ—, and —CH₂Si(R¹²)₂—CH₂—. Here, x represents the number of repeating units, and is preferably an integer of 1 to 18. The two R¹²s are each independently a hydrogen atom or a methyl group.

In addition, in R¹¹, a hydrogen atom of the hydrocarbon group having the above structure may be replaced with a halogen atom. Examples of the halogen atom include F, Cl, Br, and I.

R¹¹ is preferably a hydrocarbon group not containing O, Si, or a halogen atom from a viewpoint of hydrophobicity and easy availability.

L¹ is a single bond or a divalent linking group connecting an unsaturated double bond and R¹¹. Examples of L¹ include an alkylene group having 1 to 8 carbon atoms, —(CH₂CH₂O)ₓ—, —(CH₂O)ₓ—, —CONH—, —COO—, and —C(═O)—. Examples of the alkylene group having 1 to 8 carbon atoms include a methylene group, an ethylene group, a propylene group, a butylene group, a pentylene group, and a hexylene group.

L¹ is preferably a single bond, —CONH—, or —COO— from a viewpoint of easy availability.

The hydrophobic monomer can be used singly or in combination of two or more types thereof. The hydrophobic monomer may be a combination of a monomer having a ring structure and a monomer having no ring structure from a viewpoint of dispersibility in a polishing agent and the like.

Specific examples of the hydrophobic monomer include: alkyl (meth)acrylates such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, n-pentyl (meth)acrylate, isopentyl (meth)acrylate, n-hexyl (meth)acrylate, 2-ethylhexyl (meth)acrylate, isooctyl (meth)acrylate, n-dodecyl (meth)acrylate, and stearyl (meth)acrylate;
(meth)acrylates having a ring structure such as 1-methylcyclopentyl acrylate, cyclohexyl (meth)acrylate, and benzyl (meth)acrylate;
(meth)acrylamide derivatives such as (meth)acrylamide, N,N-dimethyl (meth)acrylamide, N,N-diethyl (meth)acrylamide, N,N-dibutyl (meth)acrylamide, N-tert-butylacrylamide, N-phenyl (meth)acrylamide, and N-benzyl (meth)acrylamide; and
vinyl-based monomers such as styrene, methylstyrene, vinyltoluene, p-t-butylstyrene, chloromethylstyrene, vinyl chloride, vinylidene chloride, vinyl fluoride, and vinylidene fluoride.

Among the above, it is preferable to contain an alkyl (meth)acrylate or styrene, and the alkyl (meth)acrylate is more preferably an alkyl (meth)acrylate having an alkyl group having 1 to 6 carbon atoms.

### (Anionic Monomer)

The anionic monomer is a monomer having an anionic group or a salt thereof. The anionic group is strongly adsorbed on the stopper film and acts as a protective film of the stopper film. Examples of the anionic monomer include a compound having an unsaturated bond and an anionic group. Examples of the anionic group include a carboxy group (—COOH), a sulfo group (—SO₃H), a phosphonic acid (—P(—OH)(—OR)(═O)), a phosphate (—OP(—OH)(—OR)(═O)), a phenolic hydroxy group, or salts thereof. Provided that R is a hydrogen atom or an alkyl group. Hereinafter, an anionic group and a salt thereof may be collectively referred to as “anionic groups or the like”.

The anionic monomer preferably contains a compound represented by the following formula (5) from a viewpoint of interaction with the stopper film.

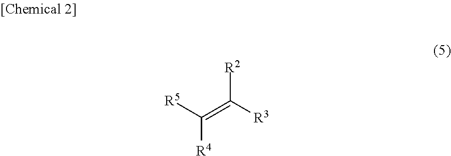

in which
R², R³, R⁴, and R⁵ are each independently a hydrogen atom, a hydrocarbon group, or a group having an anionic group or a salt thereof, at least one of R² to R⁵ is a group having an anionic group or a salt thereof, and when the compound has two or more carboxy groups in a molecule thereof, the carboxy groups may form an anhydride.

Examples of the hydrocarbon group in R² to R⁵ include an alkyl group, an aryl group, and an aralkyl group. Specific examples of the alkyl group, the aryl group, and the aralkyl group include those similar to the specific examples of the R¹¹. In the present polishing agent, the hydrocarbon group in R² to R⁵ is preferably an alkyl group having 1 to 6 carbon atoms from a viewpoint of interaction between the anionic group and the stopper film, and in particular, is preferably a methyl group or an ethyl group, and more preferably a methyl group.

The group having an anionic group or the like in R² to R⁵ preferably has a structure of -L²-R²¹.

L² is a single bond or a divalent linking group connecting an unsaturated double bond and R²¹. Examples of L² include an alkylene group having 1 to 8 carbon atoms, a phenylene group, —(CH₂CH₂O)ₓ—R²²—, —(CH₂O)ₓ—R²²—, —CONH—R²²—, and —COO—R²²—. Provided that x is an integer of 1 to 18, and R²² is preferably a single bond or an alkylene group having 1 to 8 carbon atoms.

Examples of the alkylene group in L² and R²² include a methylene group, an ethylene group, a propylene group, a butylene group, a pentylene group, and a hexylene group, and may have a halogen atom as a substituent.

L² is preferably a single bond, —CONH—R²²—, or —COO—R²²— from a viewpoint of easy availability of monomers and the like.

R²¹ is a carboxy group, a sulfo group, a phosphate, a phosphonic acid, a hydroxyphenyl group, or a salt thereof.

When the anionic group is a salt, examples of a counter cation thereof include an alkali metal ion, an alkaline earth metal ion, and an ammonium ion. Among them, an alkali metal ion or an ammonium ion is preferable, a sodium ion, a potassium ion or an ammonium ion is more preferable, and a sodium ion or a potassium ion is still more preferable.

In particular, the anionic group in R²¹ is preferably a carboxy group, a sulfo group, or a salt thereof, and more preferably a carboxy group or a salt thereof from a viewpoint of stability of the polymer and protection of the stopper film.

The number of anionic groups in one molecule of the anionic monomer only needs to be 1 or more, and is preferably 1 or 2 from a viewpoint of polymerizability of the polymer. When the anionic monomer has two carboxy groups in a molecule thereof, the carboxy groups may form an anhydride.

Examples of a suitable combination of R² to R⁵ in formula (5) include: (I) a combination in which R² is a group having an anionic group or the like, and R³ to R⁵ are each independently a hydrogen atom or a hydrocarbon group; (II) a combination in which R² and R³ are each a group having an anionic group or the like, and R⁴ and R⁵ are each independently a hydrogen atom or a hydrocarbon group; and (III) a combination in which R² and R⁵ are each independently a group having an anionic group or the like, and R³ and R⁴ are each independently a hydrogen atom or a hydrocarbon group. In (I) to (III), the hydrocarbon group is preferably a methyl group. In (II) and (III), the anionic group is preferably a carboxy group.

Specific examples of the anionic monomer include (meth)acrylic acid, vinylbenzoic acid, 2-carboxyethyl (meth)acrylate, allylsulfonic acid, methallylsulfonic acid, 2-(meth)acryloyloxyethyl acid phosphate, maleic acid (maleic anhydride), fumaric acid, itaconic acid, citraconic acid, mesaconic acid, and salts thereof. Among these monomers, (meth)acrylic acid, maleic acid, itaconic acid, fumaric acid, or a salt thereof is preferable, and (meth)acrylic acid, maleic acid, or a salt thereof is more preferable from a viewpoint of polymerizability.

The anionic monomer can be used singly or in combination of two or more types thereof.

### (Physical Properties of Anionic Polymer, Etc.)

In the present polishing agent, the anionic polymer has an acid value of 400 mgKOH/g or less. By using the specific anionic polymer, the selection ratio between the silicon oxide film and the stopper film is improved. The upper limit of the acid value of the specific anionic polymer is preferably 350 mgKOH/g, more preferably 300 mgKOH/g, and still more preferably 280 mgKOH/g from a viewpoint of improving the selection ratio.

In addition, the lower limit of the acid value of the specific anionic polymer is preferably 20 mgKOH/g or more, more preferably 50 mgKOH/g, still more preferably 100 mgKOH/g, and particularly preferably 150 mgKOH/g from a viewpoint of suppressing aggregation of the abrasive grains.

Note that the acid value represents a mass (mg) of potassium hydroxide required to neutralize an acid component contained in 1 g of a solid content of the polymer, and is a value measured by a method described in JIS K 0070:1992.

In the specific anionic polymer, the ratio of the hydrophobic monomer to the anionic monomer may be appropriately adjusted so that the acid value is in the above range. As an example, the ratio of the hydrophobic monomer is preferably 10 mol % or more, more preferably 20 mol % or more, still more preferably 30 mol % or more, and particularly preferably 40 mol % or more with respect to the total amount of all the monomers constituting the specific anionic polymer. By setting the content of the hydrophobic monomer to 10 mol % or more, polishing of the stopper film can be further suppressed. Also, in the specific anionic polymer, the ratio of the hydrophobic monomer is preferably 95 mol % or less, more preferably 90 mol % or less, still more preferably 85 mol % or less, and particularly preferably 80 mol % or less with respect to the total amount of all the monomers. By setting the content of the hydrophobic polymer to 95 mol % or less, the solubility of the specific anionic polymer is improved, and the aggregation of the abrasive grains and the aggregation of the specific anionic polymer are suppressed.

The specific anionic polymer may be a random polymer in which the hydrophobic monomer and the anionic monomer are randomly arranged, or may be a block polymer having a block of a hydrophobic monomer and a block of an anionic monomer.

The solubility of the specific anionic polymer in water is preferably 5 mg/100 g-H₂O or more, and more preferably 10 mg/100 g-H₂O or more at 25° C. from a viewpoint of storage stability and the like.

A weight average molecular weight Mw of the specific anionic polymer is preferably 1,000 to 100,000 from a viewpoint of dispersion stability of the specific anionic polymer. Among them, the lower limit value of the weight average molecular weight Mw of the specific anionic polymer is preferably 2,000, more preferably 4,000, and still more preferably 6,000. Also, among them, the upper limit value of the weight average molecular weight Mw of the specific anionic polymer is preferably 50,000, more preferably 40,000, still more preferably 30,000, still more preferably 25,000, particularly preferably 20,000, and extremely preferably 17,500.

The weight average molecular weight (Mw) is determined as a value in terms of standard polystyrene by gel permeation chromatography (GPC).

The specific anionic polymer may be a commercially available product or may be synthesized. For example, in the case of a random polymer, a hydrophobic monomer and an anionic monomer are mixed, an initiator is further added, and polymerization can be performed by a known polymerization method such as solution polymerization, bulk polymerization, or various types of radical polymerization. Among them, solution polymerization is preferable from a viewpoint of easily adjusting the weight average molecular weight of the copolymer. Also, in the case of a block polymer, for example, an anionic block may be synthesized first, and a hydrophobic monomer may be polymerized in the anionic block, and the order of polymerization of the anionic block and the hydrophobic block may be reversed in the production method. The anionic block and the hydrophobic block may be separately synthesized, and then the anionic block and the hydrophobic block may be coupled.

The content of the specific anionic polymer is preferably 0.02 mass % to 0.5 mass %, more preferably 0.05 mass % to 0.45 mass %, still more preferably 0.08 mass % to 0.4 mass %, and particularly preferably 0.1 mass % to 0.35 mass % with respect to the total mass of the polishing agent from a viewpoint of a polishing suppressing effect of the stopper film.

### <Water>

The present polishing agent contains water as a medium for dispersing abrasive grains. The type of water is not particularly limited, but pure water, ultrapure water, deionized water, or the like is preferably used in consideration of an influence on other components, prevention of contamination with impurities, and an influence on pH or the like.

### <Additive>

The present polishing agent may further contain various additives. Examples of the additive include a pH adjuster, a dispersant, a nonionic polymer, an aggregation inhibitor, a lubricant, a viscosity imparting agent, a viscosity modifier, and a preservative, and the present polishing agent may contain two or more types of additives.

### (pH Adjuster)

In order to adjust a pH to a predetermined value, the present polishing agent may contain a pH adjuster. The pH adjuster can be appropriately selected and used from an acidic compound, a basic compound, an amphoteric compound such as an amino acid, and salts thereof.

Examples of the acidic compound include an inorganic acid, an organic acid, or salts thereof. Examples of the inorganic acid include nitric acid, sulfuric acid, hydrochloric acid, and phosphoric acid, and ammonium salts thereof, sodium salts thereof, potassium salts thereof, and the like may be used.

Examples of the organic acid include a compound having a carboxy group, a sulfo group, or a phospho group as an anionic group, an ammonium salt thereof, a sodium salt thereof, and a potassium salt thereof.

Examples of the organic acid having a carboxy group include: an alkyl monocarboxylic acid such as formic acid, acetic acid, or propionic acid;
a carboxylic acid having a heterocyclic ring, such as 2-pyridine carboxylic acid, 3-pyridine carboxylic acid, 4-pyridine carboxylic acid, 2,3-pyridine dicarboxylic acid, 2,4-pyridine dicarboxylic acid, 2,5-pyridine dicarboxylic acid, 2,6-pyridine dicarboxylic acid, 3,4-pyridine dicarboxylic acid, 3,5-pyridine dicarboxylic acid, pyrazine carboxylic acid, 2,3-pyrazine dicarboxylic acid, 2-quinoline carboxylic acid, pyroglutamic acid, picolinic acid, DL-pipecolic acid, 2-furancarboxylic acid, 3-furancarboxylic acid, tetrahydrofuran-2-carboxylic acid, or tetrahydrofuran-2,3,4,5-tetracarboxylic acid;
a carboxylic acid having an alicyclic ring, such as cyclopentanecarboxylic acid, cyclohexanecarboxylic acid, cycloheptanecarboxylic acid, or cyclohexylcarboxylic acid;
a carboxylic acid having an amino group, such as alanine, glycine, glycylglycine, aminobutyric acid, N-acetylglycine, N,N-di(2-hydroxyethyl)glycine, N-(tert-butoxycarbonyl)glycine, proline, trans-4-hydroxy-L-proline, phenylalanine, sarcosine, hydantoic acid, creatine, N-[tris(hydroxymethyl)methyl]glycine, glutamic acid, or aspartic acid;
a carboxylic acid having a hydroxy group, such as lactic acid, malic acid, citric acid, tartaric acid, glycolic acid, gluconic acid, salicylic acid, 2-hydroxyisobutyric acid, glyceric acid, 2,2-bis(hydroxymethyl)propionic acid, or 2,2-bis(hydroxymethyl)butyric acid;
a carboxylic acid (keto acid) having a ketone group, such as pyruvic acid, acetoacetic acid, or levulinic acid; and
a dicarboxylic acid such as oxalic acid, malonic acid, succinic acid, fumaric acid, maleic acid, glutaric acid, adipic acid, or phthalic acid.

Examples of the basic compound include: ammonia, sodium hydroxide, potassium hydroxide, ammonium hydroxide, potassium carbonate, sodium carbonate, ammonium carbonate; a quaternary ammonium hydroxide such as tetramethylammonium hydroxide or tetraethylammonium hydroxide; and an amino alcohol such as monoethanolamine, diethanolamine, or triethanolamine.

Examples of the amphoteric compound include glycine, alanine, and phenylalanine.

The pH adjuster can be used singly or in combination of two or more types thereof. The pH of the present polishing agent is preferably 4 to 8 from a viewpoint of suppressing aggregation of the abrasive grains and further improving the selection ratio. The pH adjuster only needs to be appropriately adjusted so as to be the pH described above. As an example, the content of the pH adjuster can be 0.005 mass % to 2.0 mass %, and is preferably 0.01 mass % to 1.5 mass %, and more preferably 0.01 mass % to 0.3 mass % with respect to the total amount of the present polishing agent.

### (Dispersant)

The present polishing agent may contain a dispersant in order to improve dispersibility of the abrasive grains. Examples of the dispersant include an anionic surfactant, a cationic surfactant, a nonionic surfactant, and an amphoteric surfactant, and one or two or more of these can be used.

As the anionic surfactant, a polymer having a carboxy group, an ammonium carboxylate, or the like is preferable, and polyacrylic acid or a polyacrylate is preferable.

Examples of the cationic surfactant include a diallyldimethylammonium chloride polymer, a diallyldimethylammonium chloride/sulfur dioxide copolymer, a diallyldimethylammonium chloride/acrylamide copolymer, a diallyldimethylammonium chloride maleic acid copolymer, and a maleic acid/diallyldimethylammonium ethyl sulfate/sulfur dioxide copolymer.

A weight average molecular weight of the surfactant is preferably 10,000 to 100,000 from a viewpoint of polishing a polishing surface at a higher speed.

When a dispersant is used, the content thereof is preferably 0.0001 mass % to 0.3 mass %, more preferably 0.001 mass % to 0.2 mass %, and still more preferably 0.01 mass % to 0.15 mass % with respect to the total mass of the polishing agent from a viewpoint of polishing a polishing surface at a higher speed.

### (Nonionic Polymer)

The present polishing agent may also contain a nonionic polymer. As the nonionic polymer, from a viewpoint of lubricity, a nonionic polymer having an ether bond is preferable, and a nonionic polymer containing an ether bond in the main chain is more preferable. Specific examples of the nonionic polymer include polyethylene glycol, polyglycerin, and water-soluble nylon.

When the nonionic polymer is used, the content ratio thereof can be 0.005 mass % to 2.0 mass %, and is preferably 0.01 mass % to 1.5 mass %, and more preferably 0.01 mass % to 0.3 mass % with respect to the total amount of the present polishing agent. When the content of the nonionic polymer is within the above range, wettability of the polishing agent with respect to the polishing surface is improved, and the contact frequency of the abrasive grains is increased, so that the polishing speed of the silicon oxide film is improved.

In the present polishing agent, when the above additives are used, the total content of the additives is preferably 0.01 mass % to 10.0 mass %, and more preferably 0.01 mass % to 5.0 mass % with respect to the total mass of the polishing agent from a viewpoint of obtaining a polishing agent having a high selection ratio between the silicon oxide film and the stopper film.

### [Method for Producing Polishing Agent]

The present polishing agent is prepared so that the above X₁ to X₃ are lower than a predetermined value while using the specific anionic polymer. The method for lowering X₁ to X₃ is not particularly limited, and examples thereof include a method in which at least a part of the anionic group of the specific anionic polymer is an alkali metal salt at the time of dissolving the specific anionic polymer. A mechanism by which coarse particles are suppressed by using an alkali metal salt of the specific anionic polymer is not clear in some aspects, but is presumed as follows.

As compared with the ammonium salt of the specific anionic polymer or the like, aggregation in the molecule of the alkali metal salt of the specific anionic polymer is suppressed. It is presumed that ammonium ions and the like are adsorbed and aggregated with a plurality of anionic groups in the polymer. On the other hand, in the case of the alkali metal salt, it is presumed that the alkali metal salt is strongly adsorbed to one anionic group to suppress aggregation of the anionic group. Therefore, it is presumed that even when an anionic polymer having a low acid value is used, the anionic group efficiently interacts with the abrasive grains, and the aggregation (particle coarsening) of the abrasive grains is suppressed. As shown in Examples described later, it was recognized that this effect is maintained even when cation exchange is performed after dissolution of the specific anionic polymer to form an ammonium salt or the like. From the above, it is presumed that the coarsening of the abrasive grains can be suppressed by using an alkali metal salt as at least a part of the anionic group at the time of dissolving the specific anionic polymer.

Specific examples of the method for dissolving the specific anionic polymer include methods including the following step (1) or (2).
(1) dissolving the specific anionic polymer in which the anionic group is an alkali metal salt in water; and
(2) dissolving the specific anionic polymer in an aqueous alkali metal hydroxide solution containing an alkali metal of 1.0 times, preferably 1.1 times or more the number of moles of anionic groups calculated from the acid value of the specific anionic polymer.

In the step (1) or (2), the aqueous solution may be heated as necessary in order to facilitate dissolution of the specific anionic polymer.

In addition, the aqueous solution of the anionic polymer alkali metal salt obtained in the step (1) or (2) may be subjected to ion exchange with ammonium ions or amine ions by removing alkali metal ions using an ion exchange membrane. According to this method, it is possible to suppress metal contamination when a semiconductor component is manufactured using the present polishing agent, which is preferable.

Examples of the alkali metal include lithium, sodium, potassium, rubidium, and cesium, and sodium or potassium is preferable from a viewpoint of suppressing coarsening of the abrasive grains.

In consideration of the method for dissolving the specific anionic polymer described above, the method for producing the polishing agent is preferably specifically (A) a method of preparing each of a dispersion of abrasive grains and an aqueous solution of the specific anionic polymer (hereinafter, also referred to as “polishing agent additive liquid”) and mixing these; and

(B) a method of preparing each of abrasive grains, a specific anionic polymer, water or an aqueous alkali metal hydroxide solution, and additives to be used as necessary, and mixing these.

The polishing agent additive liquid in the above (A) can be prepared by the step (1) or (2) in the method for dissolving the specific anionic polymer.

In the method (B), when an aqueous alkali metal hydroxide solution is used, the amount of alkali metal is the same as that in the step (2) in the method for dissolving the specific anionic polymer.

The method (A) is preferable from a viewpoint of excellent storage stability and transportation convenience of the abrasive grain dispersion and the polishing agent additive liquid. The method (A) can also be applied in a polishing device when a polishing agent is used.

Note that, when a polishing agent is prepared by mixing a dispersion of abrasive grains and a polishing agent additive liquid which are two separate liquids, each of the concentration of the abrasive grains in the dispersion and the concentration of an anionic polymer and an acidic compound in the polishing agent additive liquid is concentrated to 2 to 100 times the concentration at the time of using the polishing agent, and may be diluted to a predetermined concentration at the time of use. More specifically, for example, when each of the concentration of the abrasive grains in the dispersion and the concentration of the anionic polymer and the acidic compound in the additive liquid is concentrated to 10 times, 10 parts by mass of the dispersion, 10 parts by mass of the polishing agent additive liquid, and 80 parts by mass of water are mixed and stirred to obtain a polishing agent.

By adding the polishing agent additive liquid to the dispersion of abrasive grains, it is possible to suppress coarsening of the abrasive grains and suppress polishing scratches while maintaining a high polishing speed of the silicon oxide film.

In the polishing agent additive liquid, the content ratio (concentration) of the anionic polymer is preferably 0.001 to 30 mass %, more preferably 0.01 to 20 mass %, and still more preferably 0.1 to 10 mass % with respect to the amount of the entire polishing agent additive liquid.

In the dispersion of abrasive grains, the content ratio of abrasive grains is preferably 0.2 to 40 mass %, more preferably 1 to 20 mass %, and still more preferably 5 to 10 mass %.

### [Polishing Method]

A polishing method according to the present invention is a polishing method in which a polishing surface and a polishing pad are brought into contact with each other while a polishing agent is supplied, and polishing is performed by relative movement between the polishing surface and the polishing pad, and is a method in which a polishing surface containing silicon oxide of a semiconductor substrate is polished using the polishing agent according to the present invention as the polishing agent.

Here, examples of the polishing surface to be polished include a surface including a surface made of silicon dioxide of a semiconductor substrate, a blanket wafer in which a stopper film and a silicon oxide film are laminated on a surface of a semiconductor substrate, and a pattern wafer in which these film types are arranged in a pattern. Preferable examples of the semiconductor substrate include a substrate for STI. The polishing agent of the present invention is also effective for polishing for planarizing an interlayer insulating film between multilayer wiring lines in manufacture of a semiconductor device.

Examples of the silicon oxide film in the substrate for STI include a so-called PE-TEOS film formed by a plasma CVD method using tetraethoxysilane (TEOS) as a raw material. In addition, examples of the silicon oxide film include a so-called HDP film formed by a high-density plasma CVD method. In addition, a HARP film or an FCVD film formed by another CVD method, or an SOD film formed by spin coating can also be used. Examples of a silicon nitride film include a film formed by a low-pressure CVD method or a plasma CVD method using silane or dichlorosilane and ammonia as raw materials, and a film formed by an ALD method. In addition, examples of a polysilicon film include a polycrystalline grain-shaped film obtained by forming a film by a low-pressure CVD method or a plasma CVD method using silane as a raw material and then heat-treating the film.

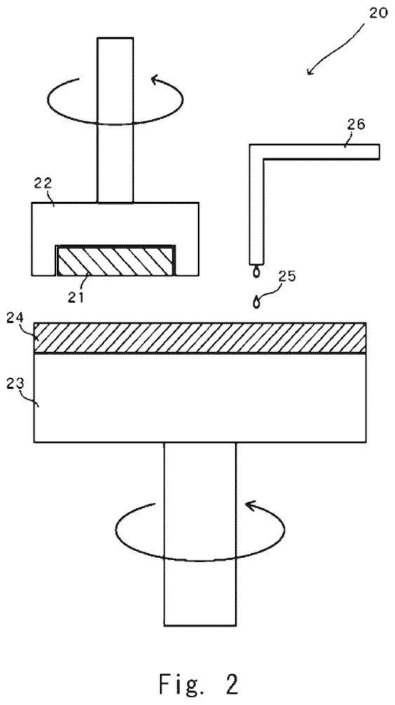

A known polishing device can be used for the present polishing method. FIG. 2 is a schematic view illustrating an example of a polishing device. A polishing device 20 illustrated in the example of FIG. 2 includes a polishing head 22 that holds a semiconductor substrate 21 such as an STI substrate, a polishing table 23, a polishing pad 24 attached to a surface of the polishing table 23, and a polishing agent supply pipe 26 that supplies a polishing agent 25 to the polishing pad 24. While the polishing agent 25 is supplied from the polishing agent supply pipe 26, a polishing surface of the semiconductor substrate 21 held by the polishing head 22 is brought into contact with the polishing pad 24, and the polishing head 22 and the polishing table 23 are relatively rotated to perform polishing.

The polishing head 22 may perform not only the rotational movement but also linear movement. In addition, each of the polishing table 23 and the polishing pad 24 may have a size equal to or smaller than the semiconductor substrate 21. In this case, it is preferable to be able to polish the entire polishing surface of the semiconductor substrate 21 by relatively moving the polishing head 22 and the polishing table 23. Furthermore, the polishing table 23 and the polishing pad 24 do not have to perform the rotational movement, and may move in one direction, for example, in a belt type form.

Polishing conditions of such a polishing device 20 are not particularly limited, but by applying a load to the polishing head 22 and pressing the polishing head 22 against the polishing pad 24, polishing pressure can be further increased, and the polishing speed can be improved. The polishing pressure is preferably about 0.5 to 50 kPa, and more preferably about 3 to 40 kPa from a viewpoint of uniformity and flatness in the polishing surface of the semiconductor substrate 21 at a polishing speed, and prevention of polishing defects such as scratches. Rotation speeds of the polishing table 23 and the polishing head 22 are preferably about 50 to 500 rpm. In addition, a supply amount of the polishing agent 25 is appropriately adjusted according to the composition of the polishing agent, the above-described polishing conditions, and the like.

As the polishing pad 24, one made of a nonwoven fabric, foamed polyurethane, a porous resin, a non-porous resin, or the like can be used. A surface of the polishing pad 24 may be grooved in a lattice shape, a concentric shape, a spiral shape, or the like in order to promote supply of the polishing agent 25 to the polishing pad 24 or to allow a certain amount of the polishing agent 25 to be accumulated in the polishing pad 24. In addition, if necessary, polishing may be performed while a surface of the polishing pad 24 is conditioned by bringing a pad conditioner into contact with the surface of the polishing pad 24.

According to the present polishing method, a high selection ratio between the silicon oxide film and the stopper film can be obtained while suppressing polishing scratches, and polishing with high flatness can be implemented.

### [Method for Manufacturing Semiconductor Component]

A method for manufacturing a semiconductor component according to the present embodiment is to obtain a semiconductor component by segmenting a semiconductor substrate having a polishing surface polished by the polishing method according to the present invention.

The method for manufacturing a semiconductor component according to the present disclosure includes a segmenting step of segmenting a semiconductor substrate having at least a polishing surface polished by the above polishing method. Examples of the segmenting step include a step of dicing the semiconductor substrate (for example, a semiconductor wafer) by a known method such as blade dicing, laser dicing, or plasma dicing to obtain a semiconductor component which is a semiconductor chip.

The present method for manufacturing a semiconductor component may further include a joining step of joining another member onto a polishing surface of the semiconductor chip. Through this step, a semiconductor component as a joint body is obtained.

Examples of the other member include a second semiconductor chip and a rewiring layer. Note that the second semiconductor chip may be a semiconductor chip obtained by the manufacturing method of the present disclosure, or may be a semiconductor chip obtained by another method. The joining step may be, for example, a step of directly disposing another member on the polishing surface and directly joining the polishing surface and the another member by fusion joining, surface activation joining, or the like, or may be a step of joining the polishing surface and another member via an adhesive layer. Examples of the adhesive layer include a metal layer such as solder or copper, a glass layer, and a resin layer such as polyimide or epoxy.

The present disclosure can further provide an electronic device including at least one semiconductor component having a polishing surface polished by the polishing method of the present disclosure.

### EXAMPLES

Hereinafter, the present invention will be specifically described with reference to Practical Examples and Comparative Examples, but the present invention is not limited to these Examples. Examples 1 to 4 are Practical Examples, and Examples 5 to 9 are Comparative Examples.

### [Measurement Method]

<pH>

A pH was measured using a pH meter HM-30R manufactured by DKK-TOA CORPORATION at a temperature of 25±5° C.

### <Average Particle Size>

An average particle size was measured using a laser scattering/diffraction type particle size distribution measuring device (manufactured by HORIBA, Ltd., device name: LA-950).

### <Acid Value>

An acid value was measured according to the method described in JIS K 0070:1992.

### <Weight Average Molecular Weight (Mw)>

A weight average molecular weight (Mw) was measured under the following conditions by gel permeation chromatography (GPC).
Device HLC-8320GPC (manufactured by Tosoh Corporation)
Column TSKgel GMPWXL (manufactured by Tosoh Corporation)
Detector RI detector polarity (+)
Eluent 0.2 M-NaNO₃ aqueous solution
Flow rate 1.0 mL/min, column temperature 40° C.
Calculated by conversion using standard PEO/PEG
   <X₁ to X₃>

Each polishing agent was diluted with water so as to have an abrasive grain concentration of about 1/12000 mass % to be used as a test liquid, and the number of particles having a particle size of 0.56 μm or more, the number of particles having a particle size of 0.79 μm or more, and the number of particles having a particle size of 0.98 μm or more were each measured by the above-described method.

Also, in the abrasive grain dispersion as a reference, polyacrylic acid was used as a dispersant, the abrasive grain concentration was adjusted to about 1/12000 mass %, and the number of particles having a particle size of 0.56 μm or more, the number of particles having a particle size of 0.79 μm or more, and the number of particles having a particle size of 0.98 μm or more were each measured by the same method as described above.

A particle counter (AccuSizer series manufactured by Entegris) was used as a measuring device, and the measurement was performed at a measurement temperature in a range of 28±1° C.

### [Abrasive Grain Dispersion]

As the abrasive grains, ceria particles having an average particle size of 100 nm and a ceria content ratio of 95 mass % or more were used. The ceria particles were dispersed in water to prepare an abrasive grain dispersion containing 0.33 mass % of the ceria particles.

### Polishing Agent Additive Liquid

### Example 1

A styrene/maleic acid copolymer (weight average molecular weight: 8,000, acid value: 350 mgKOH/g, molar ratio of styrene and maleic acid: 2:1) was dissolved in an aqueous potassium hydroxide solution containing potassium hydroxide of 1.1 times or more the number of moles of anionic groups calculated from the acid value thereof while heating to 60° C. Subsequently, cation exchange of the styrene-maleic acid copolymer potassium salt was performed using an ion exchange membrane to obtain a styrene/maleic acid copolymer ammonium salt aqueous solution. Then, water and a pH adjuster were added so as to have a pH of 5.5, thereby obtaining a polishing agent additive liquid containing 0.2 mass % of a styrene/maleic acid copolymer ammonium salt.

### Example 2

A styrene/maleic acid copolymer (weight average molecular weight: 10,000, acid value: 275 mgKOH/g, molar ratio of styrene and maleic acid: 3:1) was dissolved in an aqueous potassium hydroxide solution containing potassium hydroxide of 1.1 times or more the number of moles of anionic groups calculated from the acid value thereof while heating to 60° C. Subsequently, water and a pH adjuster were added so as to have a pH of 5.5, thereby obtaining a polishing agent additive liquid containing 0.2 mass % of styrene/maleic acid copolymer potassium salt.

### Example 3

A styrene/maleic acid half ester copolymer (weight average molecular weight: 5,000 to 10,000, acid value: 220 mgKOH/g) was dissolved in an aqueous potassium hydroxide solution containing potassium hydroxide of 1.1 times or more the number of moles of anionic groups calculated from the acid value thereof while heating to 60° C. Subsequently, water and a pH adjuster were added so as to have a pH of 5.5, thereby obtaining a polishing agent additive liquid containing 0.2 mass % of styrene/maleic acid half ester copolymer potassium salt.

### Example 4

A methyl acrylate/butyl acrylate/methacrylic acid copolymer (weight average molecular weight: 16,000, acid value: 150 mgKOH/g) was dissolved in a KOH aqueous solution containing KOH of 1.1 times or more the number of moles of anionic groups calculated from the acid value thereof while heating to 60° C. Subsequently, water and a pH adjuster were added so as to have a pH of 6, thereby obtaining a polishing agent additive liquid containing 0.6 mass % of methyl acrylate/butyl acrylate/methacrylic acid copolymer potassium salt.

### Example 5

The same styrene/maleic acid copolymer as in Example 1 was dissolved in an ammonia aqueous solution containing ammonia of 1.1 times or more the number of moles of anionic groups calculated from the acid value thereof while heating to 60° C. Subsequently, water and a pH adjuster were added so as to have a pH of 5.5, thereby obtaining a polishing agent additive liquid containing 0.2 mass % of a styrene/maleic acid copolymer ammonium salt.

### Example 6

The same styrene/maleic acid copolymer as in Example 2 was dissolved in an ammonia aqueous solution containing ammonia of 1.1 times or more the number of moles of anionic groups calculated from the acid value thereof while heating to 60° C. Subsequently, water and a pH adjuster were added so as to have a pH of 5.5, thereby obtaining a polishing agent additive liquid containing 0.2 mass % of a styrene/maleic acid copolymer ammonium salt.

### Example 7

The same styrene/maleic acid half ester copolymer as in Example 3 was dissolved in an ammonia aqueous solution containing ammonia of 1.1 times or more the number of moles of anionic groups calculated from the acid value thereof while heating to 60° C. Subsequently, water and a pH adjuster were added so as to have a pH of 5.5, thereby obtaining a polishing agent additive liquid containing 0.2 mass % of styrene/maleic acid half ester copolymer ammonium salt.

### Example 8

The same methyl acrylate/butyl acrylate/methacrylic acid copolymer as in Example 4 was dissolved in an ammonia aqueous solution containing ammonia of 1.1 times or more the number of moles of anionic groups calculated from the acid value thereof while heating to 60° C. Subsequently, water and a pH adjuster were added so as to have a pH of 6, thereby obtaining a polishing agent additive liquid containing 0.6 mass % of methyl acrylate/butyl acrylate/methacrylic acid copolymer ammonium salt.

### Example 9

A styrene/methacrylic acid copolymer (weight average molecular weight: 50,000, acid value: 500 mgKOH/g) was dissolved in an ammonia aqueous solution containing ammonia of 1.1 times or more the number of moles of anionic groups calculated from the acid value thereof while heating to 60° C. Subsequently, water and a pH adjuster were added so as to have a pH of 5, thereby obtaining a polishing agent additive liquid containing 0.6 mass % of a styrene/methacrylic acid copolymer ammonium salt.

### [Polishing Agent]

The abrasive grain dispersion and each of the polishing agent additive liquids for Examples 1 to 9 were mixed at a mass ratio of 1:1 to prepare polishing agents of Examples 1 to 9.

### [Evaluation]

The compositions of the respective polishing agents of Examples 1 to 9 and calculation results of X₁, X₂, and X₃ are shown in Table 1.

TABLE 1

| | | Example 1 | Example 2 | Example 3 | Example 4 |
|---|---|---|---|---|---|
| Abrasive | Type | Ceria particle | | | |
| grain | Particle size | 100 | | | |
| | (nm) | | | | |
| | Content | 0.167 | | | |
| | (mass %) | | | | |
| Anionic | Type | Styrene/maleic | Styrene/maleic | Styrene/maleic | Methyl |
| polymer | | acid copolymer | acid copolymer | acid half ester | acrylate/butyl |
| | | ammonium salt | potassium salt | copolymer | acrylate/methacrylic |
| | | | | potassium salt | acid copolymer |
| | | | | | potassium salt |
| | Molecular weight | 8000 | 10000 | 5000 to 10000 | 16000 |
| | Acid value | 350 | 275 | 220 | 150 |
| | (mgKOH/g) | | | | |
| | Content | 0.1 | 0.1 | 0.1 | 0.3 |
| | (mass %) | | | | |
| | Dissolution | KOH | KOH | KOH | KOH |
| | method | | | | |
| pH | | 5.8 | 5.8 | 5.8 | 6.5 |
| Evaluation | X₁ | 0.67 | 0.83 | 0.72 | 1.31 |
| | X₂ | 1.02 | 0.95 | 1.67 | 4.65 |
| | X₃ | 1.24 | 1.02 | 4.15 | 8.39 |

| | | Example 5 | Example 6 | Example 7 | Example 8 | Example 9 |
|---|---|---|---|---|---|---|
| Abrasive | Type | Ceria particle | | | | |
| grain | Particle size | 100 | | | | |
| | (nm) | | | | | |
| | Content | 0.167 | | | | |
| | (mass %) | | | | | |
| Anionic | Type | Styrene/maleic | Styrene/maleic | Styrene/maleic | Methyl | Styrene/maleic |
| polymer | | acid copolymer | acid copolymer | acid half ester | acrylate/butyl | acid copolymer |
| | | ammonium salt | ammonium salt | copolymer | acrylate/methacrylic | ammonium salt |
| | | | | ammonium salt | acid copolymer | |
| | | | | | ammonium salt | |
| | Molecular weight | 8000 | 10000 | 5000 to 10000 | 16000 | 50000 |
| | Acid value | 350 | 275 | 220 | 150 | 500 |
| | (mgKOH/g) | | | | | |
| | Content | 0.1 | 0.1 | 0.1 | 0.3 | 0.3 |
| | (mass %) | | | | | |
| | Dissolution | NH3 | NH3 | NH3 | NH3 | NH3 |
| | method | | | | | |
| pH | | 5.6 | 5.9 | 5.8 | 6.5 | 5.7 |
| Evaluation | X₁ | 2.56 | 10.65 | 6.28 | 5.46 | 0.53 |
| | X₂ | 12.15 | 116.74 | 44.55 | 121.30 | 0.69 |
| | X₃ | 20.33 | 270.98 | 103.81 | 156.85 | 1.17 |

As shown in Example 9, in the case of the anionic polymer having a high acid value, the interaction with the abrasive grains is excellent even when the anionic polymer is dissolved in an ammonia aqueous solution, and particle coarsening of the abrasive grains is suppressed. On the other hand, in Examples 5 to 8 in which the anionic polymer having a low acid value was used, the particle coarsening of the abrasive grains was observed, and it is found that it was difficult to suppress aggregation of the abrasive grains in the anionic polymer having an acid value of 400 mgKOH/g or less. Meanwhile, even when the same polymer as in Examples 5 to 8 is used, in Examples 1 to 4 in which the alkali metal salt of the anionic polymer was used at the time of dissolution, the suppression of particle coarsening of the abrasive grains was observed. In the polishing agents of Examples 1 to 4, it is presumed that the anionic polymer is dispersed without being aggregated, and the interaction with the abrasive grains is excellent.

Next, the following filter test was performed using the polishing agents of Examples 2 and 6.

### <Filter Test>

A polypropylene filter (pore size: 1 μm) was prepared as a filter. A polishing agent was passed through the filter at a flow rate of 1 L/min, and a differential pressure after a lapse of 1.5 minutes was measured. No differential pressure was observed at the start of the filter test.

In the polishing agent of Example 6, an increase in differential pressure was observed in the filter test, a differential pressure of 0.05 MP occurred after a lapse of 2 minutes, and coarse particles that could not pass through the filter were observed. It is presumed that the coarse particles are likely to cause polishing scratches on the polishing surface.

On the other hand, in the polishing agent of Example 2 in which X₁ to X₃ are lower than the predetermined value, an increase in differential pressure was not observed in the filter test, and it was observed that coarse particles that could not pass through the filter were not generated.

As described above, according to the present polishing agent in which X₁ is 1.5 or less, X₂ is 7.0 or less, and/or X₃ is 10 or less, even when an anionic polymer having a low acid value is used, the generation of coarse particles can be suppressed, and the occurrence of polishing scratches that can occur on the polishing surface can be suppressed.

### <Evaluation of Polishing Scratches>

Polishing was performed using the polishing agents of Examples 1, 2, 5, and 7 under the following conditions.
Polishing device Fully automatic CMP device (manufactured by Ebara Corporation, FREX300X)
Polishing pad Two-layer pad (manufactured by Nitta DuPont Incorporated, IC-1570)
Conditioner of polishing pad Diamond pad conditioner (manufactured by 3M, A165)

| | | |
|---|---|---|
| Polishing pressure | 21 | kPa |
| Rotation speed of polishing table | 100 | rpm |
| Rotation speed of polishing head | 102 | rpm |
| Supply speed of polishing agent | 250 | mL/min |

Polishing target A wafer with a silicon dioxide film, in which a silicon dioxide film is formed on a 12 inch silicon substrate by plasma CVD using tetraethoxysilane or monosilane as a raw material

Each wafer after polishing was sufficiently brush-cleaned using a fluorine-based cleaning agent and dried, a laser was then made incident on the wafer surface by a wafer surface inspection system (manufactured by TAKANO Co., Ltd., WM-10), and the number of polishing scratches having a size of 0.1 μm or more was measured using the reflected light. Note that a region excluding a region of 10 mm in width from the outer edge of the wafer was set as a measurement target.

As a result of the evaluation of polishing scratches, when the number of polishing scratches per unit area in Example 5 was 1, it was 0.71 in Example 1, 0.79 in Example 2, and 1.93 in Example 7. As described above, it was shown that the polishing agent of the present disclosure can remarkably suppress the occurrence of polishing scratches.

According to the present invention, high-speed polishing can be implemented, for example, in CMP of a polishing surface including an insulating film. Therefore, the polishing method of the present invention is suitable for polishing an insulating film for STI in manufacture of a semiconductor device.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A polishing agent, comprising abrasive grains, an anionic polymer or a salt thereof, and water, wherein:
an acid value of the anionic polymer is 400 mgKOH/g or less, and
at least one of the following conditions is satisfied:
X₁ determined from the following formula (1) is 1.5 or less;
X₂ determined from the following formula (2) is 7.0 or less; and
X₃ determined from the following formula (3) is 10 or less,
$${X}_{1} = {N}_{11} / {N}_{12} \qquad ( 1 )$$
$${X}_{2} = {N}_{21} / {N}_{22} \qquad ( 2 )$$
$${X}_{3} = {N}_{31} / {N}_{32} \qquad ( 3 )$$
where
N₁₁ is the number of particles having a particle size of 0.56 μm or more contained per unit mass of the abrasive grains in the polishing agent,
N₁₂ is the number of particles having a particle size of 0.56 μm or more contained per unit mass of abrasive grains in an abrasive grain dispersion containing the abrasive grains, a dispersant, and water,
N₂₁ is the number of particles having a particle size of 0.79 μm or more contained per unit mass of the abrasive grains in the polishing agent,
N₂₂ is the number of particles having a particle size of 0.79 μm or more contained per unit mass of the abrasive grains in the abrasive grain dispersion,
N₃₁ is the number of particles having a particle size of 0.98 μm or more contained per unit mass of the abrasive grains in the polishing agent, and
N₃₂ is the number of particles having a particle size of 0.98 μm or more contained per unit mass of the abrasive grains in the abrasive grain dispersion.

2. The polishing agent according to claim 1, wherein the abrasive grains in the polishing agent contain at least one selected from the group consisting of silica particles, alumina particles, zirconia particles, cerium compound particles, titania particles, germania particles, composite particles thereof, and core-shell type particles.

3. The polishing agent according to claim 2, wherein the abrasive grains in the polishing agent contain cerium compound particles.

4. The polishing agent according to claim 2, wherein the abrasive grains in the polishing agent contain ceria particles.

5. The polishing agent according to claim 1, wherein a content of the abrasive grains in the polishing agent is 0.01 mass % to 10.0 mass % with respect to a total mass of the polishing agent.

6. The polishing agent according to claim 1, wherein the anionic polymer is a copolymer containing a hydrophobic monomer and an anionic monomer.

7. The polishing agent according to claim 1, wherein the anionic polymer has a weight average molecular weight of 2,000 to 50,000.

8. The polishing agent according to claim 1, wherein a content of the anionic polymer is 0.02 mass % to 5 mass % with respect to a total mass of the polishing agent.

9. The polishing agent according to claim 1, further comprising a pH adjuster.

10. The polishing agent according to claim 1, having a pH of 4 to 8.

11. A polishing method, comprising:
bringing a polishing surface of a semiconductor substrate and a polishing pad into contact with each other while supplying the polishing agent according to claim 1, and
performing polishing by relative movement between the polishing surface and the polishing pad.

12. A method for manufacturing a semiconductor component, the method comprising:
segmenting the semiconductor substrate having a polishing surface polished by the polishing method according to claim 11 to obtain the semiconductor component.

13. A method for producing a polishing agent additive liquid containing an anionic polymer or a salt thereof having an acid value of 400 mgKOH/g or less, the method comprising the following step (1) or (2):
(1) dissolving an alkali metal salt of the anionic polymer in water; and
(2) dissolving the anionic polymer in an aqueous alkali metal hydroxide solution containing an alkali metal of 1.0 times or more the number of moles of anionic groups calculated from the acid value of the anionic polymer.

14. The method according to claim 13, wherein the alkali metal is at least one selected from the group consisting of lithium, sodium, potassium, rubidium, and cesium.

15. A method for producing the polishing agent according to claim 1, the method comprising:
mixing the abrasive grains with a polishing agent additive liquid containing the anionic polymer or the salt thereof,
wherein the polishing agent additive liquid is obtained by either dissolving an alkali metal salt of the anionic polymer in water, or dissolving the anionic polymer in an aqueous alkali metal hydroxide solution containing an alkali metal of 1.0 times or more the number of moles of anionic groups calculated from the acid value of the anionic polymer.
